(19) United States
(12) Patent Application Publication
(10) Pub. No.: US 2023/0378155 A1
(43) Pub. Date: Nov. 23, 2023

(54) SEMICONDUCTOR DEVICE

(71) Applicant: Samsung Electronics Co., Ltd., Suwon-si (KR)

(72) Inventors: Panjae Park, Suwon-si (KR); Suhyeong Choi, Suwon-si (KR); Jiwook Kwon, Suwon-si (KR); Chulhong Park, Suwon-si (KR)

(21) Appl. No.: 18/156,494

(22) Filed: Jan. 19, 2023

(30) Foreign Application Priority Data
May 23, 2022 (KR) 10-2022-0062828

(51) Int. Cl. H01L 27/02; G06F 30/392; G06F 30/394

(52) U.S. Cl. CPC H01L 27/0207; G06F 30/392; G06F 30/394

(57) ABSTRACT

A semiconductor device includes first standard cells arranged in a first row on a substrate and respectively including a first base active region, second standard cells arranged in a second row adjacent to the first row and respectively including a second base active region, a power line extending in a first direction along a boundary between the first and second standard cells, and a device isolation layer on side surfaces of the first and second base active regions, wherein, in a plan view, the first standard cells and the second standard cells have a same cell height, the first base active region of each of the first standard cells includes a first active line having a first conductivity-type and a second active line having a second conductivity-type, the second base active region of each of the second standard cells includes a third active line having the first conductivity-type and a fourth active line having the second conductivity-type, the first active lines of the first standard cells arranged in the first row have a same first width, the third active lines of the second standard cells arranged in the second row have a same second width, and the first width is narrower than the second width.

### CROSS-REFERENCE TO RELATED APPLICATION(S)

This application claims benefit of priority to Korean Patent Application No. 10-2022-0062828 filed on May 23, 2022 in the Korean Intellectual Property Office, the disclosure of which is incorporated herein by reference in its entirety.

### BACKGROUND

The present inventive concept relates to the design and manufacture of semiconductor devices.

As demand for high performance, high speed, and/or multifunctionality of semiconductor devices has increased, the degree of integration of semiconductor devices has also increased. With the trend for high integration of semiconductor devices, research for designing a layout, in particular, for efficient routing of wirings for connecting semiconductor devices, has been actively conducted.

### SUMMARY

An aspect of the present inventive concept is to provide a semiconductor device having improved productivity and electrical performance.

According to an aspect of the present inventive concept, a semiconductor device includes: first standard cells arranged in a first row on a substrate and respectively including a first base active region; second standard cells arranged in a second row adjacent to the first row on the substrate and respectively including a second base active region; a power line extending in a first direction along a boundary between the first standard cells and the second standard cells; and a device isolation layer on side surfaces of the first and second base active regions, wherein, in a plan view, the first standard cells and the second standard cells have a same cell height, the first base active region of each of the first standard cells includes a first active line having a first conductivity-type and a second active line having a second conductivity-type, different from the first conductivity-type, the second base active region of each of the second standard cells includes a third active line having the first conductivity-type and a fourth active line having the second conductivity-type, the first active lines of the first standard cells arranged in the first row have the same first width, the third active lines of the second standard cells arranged in the second row have the same second width, and the first width is narrower than the second width.

According to another aspect of the present inventive concept, a semiconductor device includes: a substrate having base active regions extending in a first direction; a plurality of standard cells respectively including a gate structure extending in a second direction, crossing the first direction, on the base active regions, and source/drain regions on the base active regions at both sides of the gate structure; and a plurality of power lines respectively extending in the first direction along boundaries of the plurality of standard cells and configured to supply power to the plurality of standard cells, wherein the plurality of standard cells are arranged in a plurality of rows having a same cell height in the second direction, each of the base active regions includes a first active line having a first conductivity-type and a second active line having a second conductivity-type, different from the first conductivity-type, the base active regions include first groups including first base active regions and second groups including second base active regions, in each of the first groups, the first base active regions include the first active lines having a first width and arranged in the first direction in one of the plurality of rows, and in each of the second groups, the second base active regions include the first active lines having a second width, different from the first width, and arranged in the first direction in one of the plurality of rows, wherein the first groups and the second groups are arranged at regular intervals in the second direction.

According to another aspect of the present inventive concept, a semiconductor device includes: a substrate having a base active region; a plurality of standard cells arranged in a plurality of rows on the substrate; and a plurality of power lines extending in a first direction along boundaries of the plurality of standard cells and configured to supply power to the plurality of standard cells, wherein each of the plurality of standard cells includes a gate structure extending in a second direction, crossing the first direction, on the base active region, and source/drain regions on the base active region at both sides of the gate structure, the plurality of power lines extend parallel to each other at equal intervals, and the base active region includes first and second base active regions having different widths in different rows among the plurality of rows and arranged in the first direction.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a block diagram illustrating a computer system for performing semiconductor design according to example embodiments.

FIG. 2 is a flowchart illustrating a method of designing and manufacturing a semiconductor device according to example embodiments.

FIG. 3A is a schematic layout diagram of a semiconductor device according to example embodiments.

FIG. 3B is a partially enlarged view of a layout diagram of a semiconductor device according to example embodiments.

FIGS. 4A and 4B are partially enlarged views of a layout diagram of a semiconductor device according to example embodiments.

FIG. 5 is a schematic layout diagram of a semiconductor device according to example embodiments.

FIG. 6 is a schematic layout diagram of a semiconductor device according to example embodiments.

FIG. 7 is a schematic layout diagram of a semiconductor device according to example embodiments.

FIG. 8 is a plan view illustrating a semiconductor device according to example embodiments.

FIGS. 9A to 9C are cross-sectional views illustrating semiconductor devices according to example embodiments.

FIG. 10 is a plan view illustrating a semiconductor device according to example embodiments.

FIG. 11A and 11B are cross-sectional views illustrating semiconductor devices according to example embodiments.

### DETAILED DESCRIPTION

Hereinafter, example embodiments of the present inventive concept will be described with reference to the accompanying drawings. The present inventive subject matter may, however, be embodied in many different forms and should not be construed as limited to the embodiments set forth herein. In the drawings, like numerals refer to like elements throughout the description and repeated descriptions may be omitted. It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

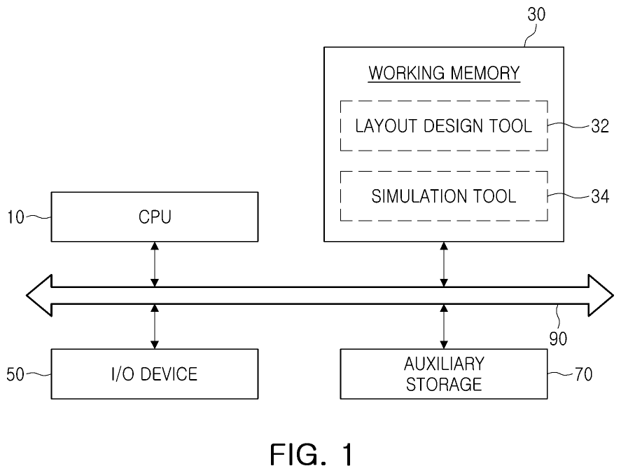

FIG. 1 is a block diagram illustrating a computer system for performing semiconductor design according to example embodiments.

Referring to FIG. 1, a computer system may include a CPU 10, a working memory 30, an input/output (I/O) device 50, and a storage device (or an auxiliary storage) 70. Here, the computer system may be an apparatus for layout design of the present inventive concept. The computer system may additionally include various design and verification simulation programs.

The CPU 10 may be configured to execute software (application programs, operating systems, device drivers) in the computer system. The CPU 10 may be configured to execute an operating system (OS) loaded into the working memory 30. The CPU 10 may be configured to execute various application programs (AP), based on the operating system. For example, the CPU 10 may be configured to execute the layout design tool 32 loaded in the working memory 30.

The operating system or the application programs may be loaded into the working memory 30. When the computer system is booted, an OS image stored in the storage device 70 may be loaded into the working memory 30 based on a booting sequence. General I/O operations of the computer system may be supported by the operating system. Similarly, the application programs may be loaded into the working memory 30 to be selected by a user or to provide a basic service. In particular, the layout design tool 32 for designing a layout of according to embodiments of the present inventive concept may also be loaded into the working memory 30 from the storage device 70.

The layout design tool 32 may have a biasing function that may change a shape and position of specific layout patterns to be different from those defined by a design rule. In addition, the layout design tool 32 may perform a design rule check (DRC) on the changed biasing data condition. The working memory 30 may be a volatile memory, such as a static random access memory (SRAM) or a dynamic random access memory (DRAM), or a nonvolatile memory, such as a PRAM, MRAM, ReRAM, FRAM, or NOR flash memory.

The working memory 30 may further include a simulation tool 34 configured to perform optical proximity correction (OPC) on designed layout data.

The I/O device 50 is configured to control user input and output from user interface devices. For example, the I/O device 50 may include a keyboard or a monitor to receive information from a designer. Using the I/O device 50, the designer may receive information on a semiconductor region or data paths requiring adjusted operating characteristics. In addition, a processing process and processing result of the simulation tool 34 may be displayed through the I/O device 50.

The storage device 70 is provided as a storage medium of a computer system. The storage device 70 may store application programs, an operating system image, and various data. The storage device 70 may be provided as a memory card (e.g., MMC, eMMC, SD, micro SD, etc.) or a hard disk drive (HDD). The storage device 70 may include a NAND-type flash memory having a relatively large storage capacity. In other embodiments, the storage device 70 may include a next-generation nonvolatile memory such as PRAM, MRAM, ReRAM, or FRAM, or NOR flash memory.

A system interconnector 90 may be a system bus for providing a network inside the computer system. The CPU 10, the working memory 30, the I/O device 50, and the storage device 70 may be electrically connected through the system interconnector 90 and exchange data with each other. However, a configuration of the system interconnector 90 is not limited to the above description, and may further include mediating units for efficient management in other embodiments.

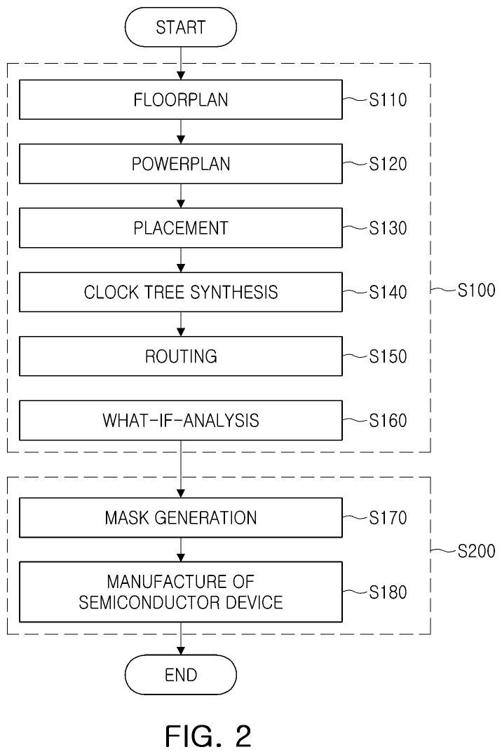

FIG. 2 is a flowchart illustrating a method of designing and manufacturing a semiconductor device according to example embodiments, and it may be understood that a design operation of the method may be implemented by the computer system described above.

Referring to FIG. 1, the method of designing and manufacturing a semiconductor device according to the present example embodiment may include a semiconductor device designing operation S100 and a semiconductor device manufacturing process operation S200.

The semiconductor device designing operation S100 is an operation of designing a layout for a circuit, and may be performed using a tool for designing a circuit. The tool may be a program including a plurality of instructions executed by a processor. Accordingly, the semiconductor device designing operation S100 may be a computer implemented operation for designing a circuit. The semiconductor device manufacturing process operation S200 is an operation of manufacturing a semiconductor device according to the designed layout and may be performed in a semiconductor process module.

First, the semiconductor device designing operation S100 may include a floorplan operation S110, a powerplan operation S120, a placement operation S130, a clock tree synthesis (CTS) operation S140, a routing operation S150, and a what-if-analysis operation S160.

The floorplan operation S110 may be an operation of physically designing a logically designed schematic circuit by cutting and moving it. In the floorplan operation S110, a memory or a functional block may be provided. In this operation, for example, functional blocks to be arranged to be adjacent to each other may be identified, and space for the functional blocks may be allocated in consideration of available space and required performance. For example, the floorplan operation S110 may include an operation of generating a site-row and an operation of forming a metal routing track in the generated site-row. The site-row is a frame for arranging standard cells stored in a cell library according to a prescribed design rule. Standard cells each having the same height may be arranged in each row. Standard cells of some rows may provide a site for arranging standard cells to have a height different from that of standard cells in other rows. The metal routing track is an imaginary line on which wirings are formed later.

The powerplan operation S120 may be an operation of arranging patterns of wirings connecting a local power source, for example, a driving voltage or a ground, to the arranged functional blocks. For example, patterns of wirings connecting power or ground may be generated so that power may be uniformly supplied to the entire chip in the form of a net. In this specification, the patterns may also be referred to as a power rail or a power line. In this operation, the wirings may be generated through various rules. For example, the wirings may be generated to have a line shape in which the power lines extend to be apart from each other on a semiconductor substrate.

The placement operation S130 is an operation of arranging patterns of elements constituting the functional block, and may include an operation of arranging standard cells. In particular, in example embodiments, each of the standard cells may include semiconductor devices and first wiring lines connected thereto. The first wiring lines may include a power transmission line connecting a power source or a ground and a wiring line configured to transmit a control signal, an input signal, or an output signal. Empty regions may be generated between the standard cells arranged in this operation, and the empty regions may be filled by filler cells. Unlike standard cells, including operable semiconductor devices and unit circuits implemented with semiconductor devices, the filler cells may be dummy regions. By this operation, a shape or size of a pattern for constituting transistors and wirings to be actually formed on the semiconductor substrate may be defined. For example, to form an inverter circuit on an actual semiconductor substrate, layout patterns, such as PMOS, NMOS, N-WELL, gate electrode, and wirings to be arranged thereon may be appropriately disposed. In an example embodiment, patterns within one functional block may be formed to have the same cell height. In this case, various layout patterns may be formed by including active regions having different lengths or different widths even though they have the same cell height.

The CTS operation S140 may be an operation of generating patterns of signal lines of a central clock related to a response time that determines the performance of the semiconductor device.

The routing operation S150 may be an operation of generating an upper and lower wiring structure or a routing structure including second wiring lines connecting the arranged standard cells. In particular, a power distribution network (PDN) may be implemented in this operation. The second wiring lines may be electrically connected to the first wiring lines in the standard cells, and may electrically connect the standard cells to each other or may be connected to a power source or a ground. In an example embodiment, the second wiring lines may be configured to be physically formed on top of the first wiring lines, but in some example embodiments, some of the second wiring lines, for example, the routing structure, may be physically formed on top of the first wiring lines, and the rest of the second wiring lines, for example, a power distribution network, may be configured to be physically formed below the semiconductor substrate.

The what-if-analysis operation S160 may be an operation of verifying and correcting the generated layout. Items to be verified may include design rule check (DRC) verifying whether the layout is correct in accordance with the design rule, electronical rule check (ERC) verifying whether the layout is correct without electrical breakage, and layout vs schematic (LVS) determining whether the layout matches a gate level net list.

In an example embodiment, a feedback operation may be included in at least one of the operations from the placement operation S130 to the what-if-analysis operation S160. The placement operation S130 to the what-if-analysis operation S160 may be performed once more by reflecting necessary corrections through the feedback operation. That is, the placement operation S130 to the what-if-analysis operation S160 may be performed a plurality of times. In the feedback operation, the arrangement relationship of the standard cells arranged in each row may be changed.

Subsequently, the semiconductor device manufacturing process operation S200 may include a mask generating operation S170 and a semiconductor device manufacturing operation S180.

The mask generating operation S170 may include an operation of generating mask data for forming various patterns on a plurality of layers by performing optical proximity correction (OPC), etc. on the layout data generated in the semiconductor device designing operation S100 and an operation of manufacturing a mask using the mask data. The OPC may be for correcting distortion that may occur in a photolithography process. The mask may be manufactured in a manner in which layout patterns are depicted using a thin chrome film applied on a glass or quartz substrate.

In the semiconductor device manufacturing operation S180, various types of exposure and etching processes may be repeatedly performed. Through these processes, shapes of patterns configured during the layout design may be sequentially formed on a semiconductor substrate, such as silicon. Specifically, various semiconductor processes are performed on the semiconductor substrate, such as a wafer, using a plurality of masks to form a semiconductor device in which an integrated circuit is implemented. The semiconductor process used in the present example embodiment may be performed by a lithography process using light, such as extreme ultraviolet (EUV), and since the mask is manufactured using the lithography process, a pitch, spacing, and/or line width of the patterns may be freely set. In addition, the semiconductor process may include a deposition process, an etching process, an ion process, a cleaning process, and the like. In addition, the semiconductor process may include a packaging process of mounting the semiconductor device on a PCB and sealing the semiconductor device with a sealing material or may include a test process of the semiconductor device or a package thereof.

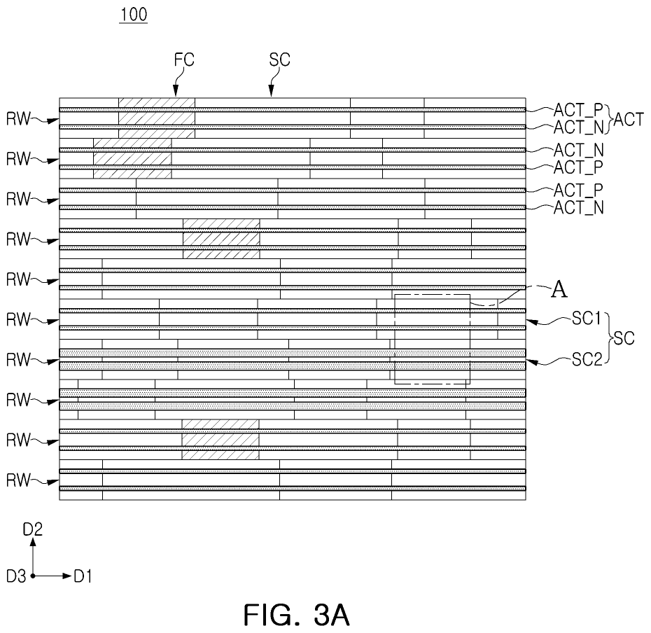

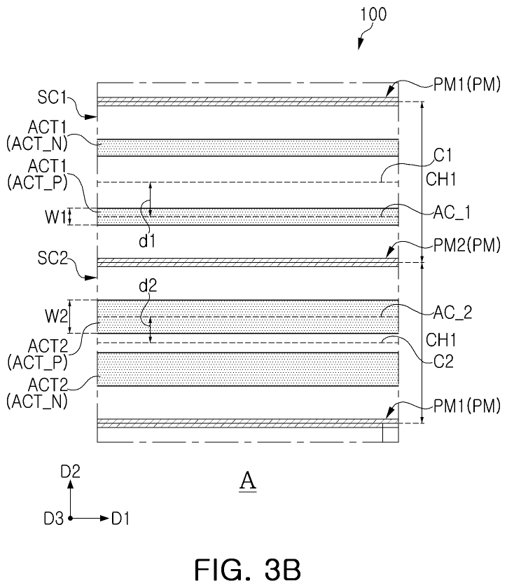

FIG. 3A is a schematic layout diagram of a semiconductor device according to example embodiments.

FIG. 3B is a partially enlarged view of a layout diagram of a semiconductor device according to example embodiments. FIG. 3B is a partially enlarged view illustrating an enlarged region ‘A’ of FIG. 3A. FIGS. 3A and 3B may be a layout designed according to the method described with reference to FIGS. 1 and 2, but may also be understood as a plan view of an actual semiconductor device manufactured based on the layout. For convenience of description, detailed cell structures are omitted and the plurality of power lines PM and the base active region ACT are mainly illustrated.

Referring to FIGS. 3A and 3B, the semiconductor device 100 may include standard cells SC and filler cells FC serving as dummy regions. The standard cells SC may be respectively arranged in a plurality of rows RW extending in a first direction D1 and arranged in a second direction D2, crossing the first direction D1 (e.g., perpendicular to the first direction).

Each of the standard cells SC has a first conductivity-type (e.g., p-type) device region and a second conductivity-type (e.g., n-type) device region arranged in the second direction D2 that is a column direction. The standard cells SC positioned in two adjacent rows, among the plurality of rows RW, may be arranged such that device regions of the same conductivity-type are adjacent to each other.

Each of the standard cells SC may include a base active region ACT extending in the first direction D1 that is a row direction. In an example embodiment, the base active region ACT may include a first active line ACT_P extending in the first direction D1 and a second active line ACT_N spaced apart from and extending parallel to the first active line ACT_P. The first active line ACT_P may be disposed in the first device region, and the second active line ACT_N may be disposed in the second device region. The first and second active lines ACT_P and ACT_N may include impurities of different conductivity-types. For example, the first active line ACT_P may have the first conductivity-type, and the second active line ACT_N may have the second conductivity-type.

The semiconductor device 100 according to example embodiments may further include a plurality of power lines PM extending in the first direction D1 along the boundaries of the standard cells SC as shown in FIG. 3B. In an example embodiment, the plurality of power lines PM may extend parallel to each other at the same intervals in the second direction D2. The plurality of power lines PM may be configured to supply power to the adjacent standard cells SC. The plurality of power lines PM may include first and second power lines PM1 and PM2 alternately disposed in the second direction D2, and the first and second power lines PM1 and PM2 may respectively supply different potentials to the standard cells SC located therebetween. For example, the first power lines PM1 may be configured to supply a first potential, and the second power lines PM2 may be configured to supply a second potential. The power line disposed at the boundary between the standard cells SC of two adjacent rows may be a shared power line shared by the adjacent standard cells.

The plurality of rows RW may include a first row R1 and a second row R2 adjacent to the first row R1, and the standard cells SC may include first standard cells SC1 arranged in the first row R1 and second standard cells SC2 arranged in second row R2.

Each of the first and second standard cells SC1 and SC2 may be a complementary metal oxide semiconductor (CMOS) device disposed between adjacent first and second power lines PM1 and PM2.

Each of the first standard cells SC1 may have the same cell height, and each of the second standard cells SC2 may have the same cell height. In the present specification, the “cell height” may be defined as a length of each of the standard cells SC in the second direction D2. The standard cells SC arranged in each row may have different widths (defined in the first direction D1) even though they have the same cell height.

The first standard cells SC1 and the second standard cells SC2 may have the same cell height as the first cell height CH1.

In an example embodiment, the first standard cells SC1 may include first base active regions ACT1 extending in the first direction D1, and the second standard cells SC2 may include second base active regions ACT2 extending in the second direction D2. In this specification, the first active line ACT_P of the second standard cells SC2 may be referred to as a ‘third active line’, and the second active line ACT_N of the second standard cells SC2 may be referred to as a ‘fourth active line’.

In the second direction D2, the first base active regions ACT1 may have a first width W1, and the second base active regions ACT2 may have a second width W2. In this specification, a width of the base active region ACT may refer to a width of the first active line ACT_P. In the first row R1, the first active line ACT_P of the first base active region ACT1 may have a uniform first width W1 and extend in the first direction D1. In the second row R2, the first active line ACT_P of the second base active region ACT2 may have a uniform second width W2 and extend in the first direction D1. That is, the first active lines ACT_P of the first standard cells SC1 arranged in the first row R1 may have the same first width W1, and the first active lines ACT_P of the second standard cells SC2 P arranged in the second row R2 may have the same second width W2.

By arranging the base active regions ACT having the same width in one row, a process defect caused by a tapered pattern may be improved, thereby providing a semiconductor device having improved productivity. The tapered pattern may refer to a base active region pattern having a portion in which a width is changed at a boundary between adjacent standard cells SC in one row. In an etching process of forming the base active regions by the tapered pattern, a dummy structure may be formed in the region in which the width is changed. The dummy structure may degrade electrical performance and reliability of the semiconductor device. Accordingly, the semiconductor device 100 according to the example embodiments may eliminate the tapered pattern to provide a semiconductor device having improved productivity.

In an example embodiment, the second active line ACT_N of each of the first base active regions ACT1 may have substantially the same width as the first width W1 of the first base active regions ACT1, and the second active line ACT_N of each of the second base active regions ACT2 may have substantially the same width as the second width W2 of the second base active region ACT2.

The first width W1 may be smaller than the second width W2. That is, the width (defined in the second direction D2) of the first base active region ACT1 disposed in the first row R1 may be smaller than the width (defined in the second direction D2) of the second base active region ACT2 disposed in the second row R2. The first standard cells SC1 including the first base active region ACT1 having a first width W1 are disposed in the first row R1 and the second standard cells SC2 including the second base active region ACT2 having the second width W2 are disposed in the second row R2, thereby securing diversity of the standard cells to provide a semiconductor device having improved electrical characteristics.

The semiconductor device 100 according to example embodiments may include standard cells SC having the same cell height provided from the same library, but the standard cells SC may include standard cells configured to perform various functions according to the width of the base active region ACT. Accordingly, the standard cells SC1 and SC2 including the base active regions ACT1 and ACT2 having the same width are arranged in a one row among the plurality of rows RW, and the standard cells SC1 and SC2 including the base active regions ACT1 and ACT2 having different widths are disposed in each row, thereby securing the diversity of the standard cells, while eliminating a tapered pattern.

Referring to FIG. 3B, a first distance d1 from a central axis C1 of each of the first standard cells SC1 in the first direction D1 to a central axis AC_1 of the first active line ACT_P of the first base active region ACT1 in the first direction D1 may be greater than a second distance d2 from a central axis C2 of each of the second standard cells SC2 in the first direction D1 to a central axis AC_2 of each of the second standard cells SC2 in the first direction D1. Each of the first standard cells SC1 may have a first side and a second side opposing each other in the second direction D2 and a first central axis C1 between the first side and the second side, each of the second standard cells SC2 may have a third side and a fourth side opposing each other in the second direction D2 and a second central axis C2 between the third side and the fourth side, each of the first active lines ACT_P of the first base active regions ACT1 may have a fifth side and a sixth side opposing each other in the second direction D2 and a third central axis AC_1 between the fifth side and the sixth side, and each of the first active lines ACT_P of the second base active regions ACT2 may have a seventh side and an eighth side opposing each other in the second direction D2 and a fourth central axis AC_2 between the seventh side and the eighth side. The first distance d1 from the first central axis C1 to the third central axis AC_1 may be greater than the second distance d2 from the second central axis C2 to the fourth central axis AC_2.

For example, in a plan view, the shortest distance from the power line PM to the base active region ACT1 of each of the first standard cells SC1 may be substantially equal to the shortest distance from the power line PM to the base active region ACT2 of each of the second standard cells SC2.

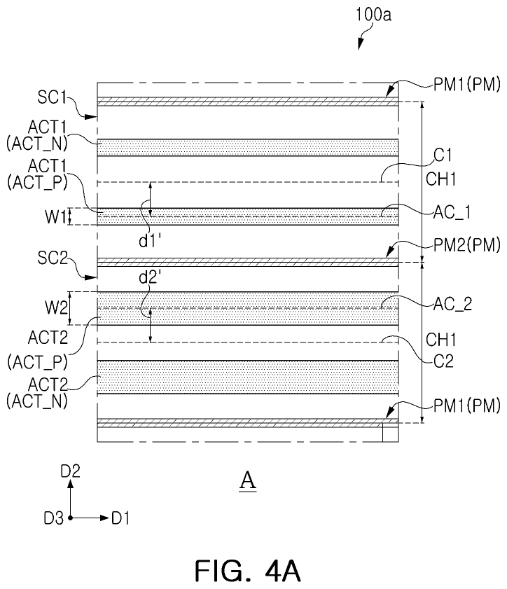

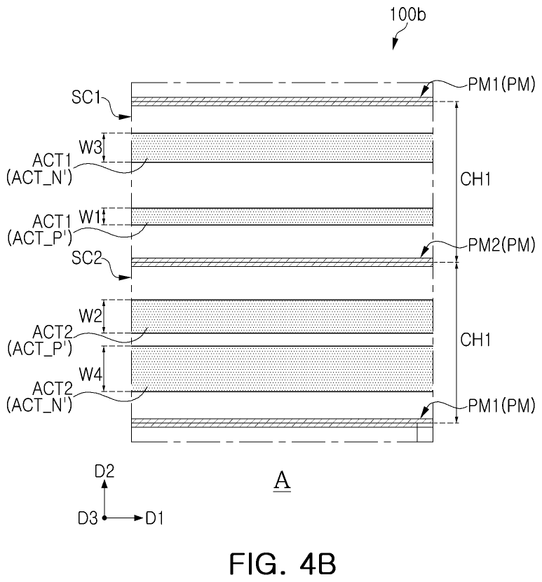

FIG. 4A is a partially enlarged view of a layout diagram of a semiconductor device according to example embodiments. Although FIG. 4A may be a layout, it may be understood as a plan view of an actual semiconductor device manufactured based on the layout.

Referring to FIG. 4A, in a semiconductor device 100a according to example embodiments, a distance d1′ from the central axis C1 of each of the first standard cells SC1 in the first direction D1 to the central axis AC_1 of the first active line ACT_P of the first base active region ACT1 in the first direction D1 may be equal to a second distance d2′ from the central axis C2 of each of the second standard cells SC2 in the first direction D1 to the central axis AC_2 of the first active line ACT_P of the second base active region ACT2.

Each of the first standard cells SC1 has a first side and a second side opposing each other in the second direction D2 and a first central axis C1 between the first side and the second side, each of the two standard cells SC2 has a third side and a fourth side opposing each other in the second direction D2 and a second central axis C2 between the third side and the fourth side, each of the first active lines ACT_P of the base active regions ACT1 has a fifth side and a sixth side opposing each other in the second direction D2 and a third central axis AC_1 between the fifth side and the sixth side, each of the first active lines ACT_P of the second base active regions ACT2 has a seventh side and an eighth side opposing each other in the second direction D2 and a fourth central axis AC_2 between the seventh side and the eighth side. A first distance d1′ from the first central axis C1 to the third central axis AC_1 may be substantially equal to a second distance d2′ from the second central axis C2 to the fourth central axis AC_2.

In a plan view, the shortest distance from the power line PM to the base active region ACT1 of each of the first standard cells SC1 may be greater than the shortest distance from the power line PM to the base active region ACT2 of each of the second standard cells SC2.

If the first standard cells SC1 and the second standard cells SC2 are arranged side by side, at least two dummy structures may be formed at the boundary between the first and second standard cells SC1 and SC2, but because the first standard cells SC1 and the second standard cells SC2 are disposed in different rows R1 and R2, the dummy structure may not be formed.

FIG. 4B is a partially enlarged view of a layout diagram of a semiconductor device according to example embodiments. Although FIG. 4A may be a layout, it may be understood as a plan view of an actual semiconductor device manufactured based on the layout.

Referring to FIG. 4B, in a semiconductor device 100b according to example embodiments, first and second active lines ACT_P′ and ACT_N′ of the first base active regions ACT1 may have a structure different from that of FIG. 3B. Each of the first active lines ACT_P′ of the first base active regions ACT1 may have the same first width W1, and the second active lines ACT_N′ of the first base active regions ACT1 may have a third width W3 different from the first width W1. However, all of the second active lines ACT_N′ may have the same third width W3. As illustrated in FIG. 4B, the third width W3 may be greater than the first width W1, but embodiments are not limited thereto and, in other embodiments, may be smaller than the first width W1.

Similarly, the first and second active lines ACT_P′ and ACT_N′ of the second base active regions ACT2 may have a different structure from that of FIG. 3B. Each of the first active lines ACT_P′ of the second base active regions ACT1 has the same second width W2, and the second active lines ACT_N′ of the second base active regions ACT2 may have a fourth width W4 different from the second width W2.

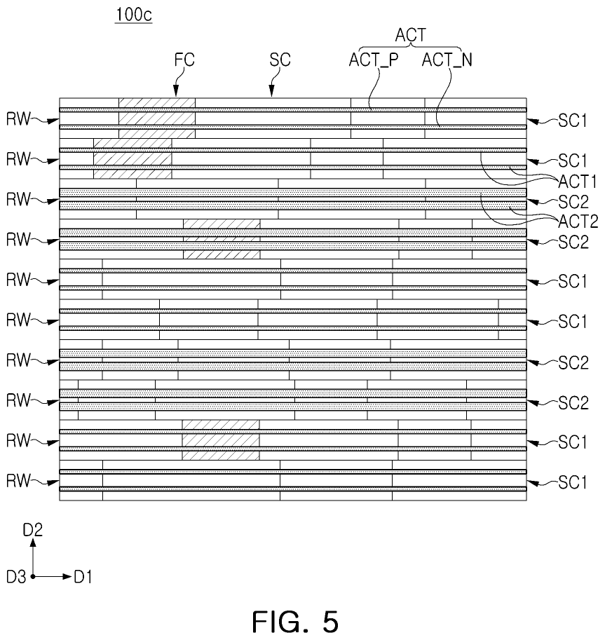

FIG. 5 is a schematic layout diagram of a semiconductor device according to example embodiments. FIG. 5 may be a layout, but may be understood as a plan view of an actual semiconductor device manufactured based on the layout.

Referring to FIG. 5, in a semiconductor device 100c according to example embodiments, the base active regions ACT may include a plurality of base active regions ACT1 and ACT2 having a constant width and arranged in the first direction D1 in each of the plurality of rows RW. The plurality of base active regions ACT1 and ACT2 may include first base active regions ACT1 having a first width W1 and second base active regions ACT2 having a second width W2. The first width W1 may be smaller than the second width W2.

In an example embodiment, with reference to FIG. 2 and FIG. 5, in the floorplan operation S110 or the placement operation S130, a plurality of base active regions ACT having a constant width and arranged in the first direction D1 may be designed. For example, in the floorplan operation S110, a design operation may be performed on the site rows having a constant width without a tapered pattern, that is, on the base active regions ACT having a constant width in the first direction D1, and a design operation of arranging standard cells including the base active regions ACT having the same width in each of the site rows may be performed in the placement operation S130.

The first standard cells SC1 including the first base active regions ACT1 having the first width W1 and the second standard cells SC2 including the second base active regions ACT2 having the second width W2 may be arranged at regular intervals.

In the plurality of adjacent rows RW, the first standard cells SC1 and the second standard cells SC2 may be arranged at an interval ratio of 2n:2. That is, in the plurality of adjacent rows RW, the first base active regions ACT1 and the second base active regions ACT2 may be arranged at an interval ratio of 2n:2. As illustrated in FIG. 5, the first and second standard cells SC1 and SC2 may be arranged in a 2:2 ratio, but n is not limited thereto and, for example, n may be an integer ranging from 1 to 4. Also, in some embodiments, n may be an integer greater than 4. As n is relatively large, a low-power device may be implemented, and as n is relatively small, a device having improved power performance may be implemented.

In an example embodiment, the value of n may be determined in the floorplan operation S110 or the placement operation S130 of FIG. 2.

The base active regions ACT1 and ACT2 may include first groups including the first base active regions ACT1 and second groups including the second base active regions ACT2. In each of the first groups, the first base active regions ACT1 include the first active lines ACT_P having the first width and arranged in the first direction D1 in one of the plurality of rows RW. In each of the first groups, the first active lines ACT_P may have the same width. In each of the second groups, the second base active regions ACT2 include first active lines ACT_P having the second width and arranged in the first direction D1 in one of the plurality of rows RW. In each of the second groups, the first active lines ACT_P may have the same width. The first groups and the second groups may be arranged at regular intervals in the second direction D2. In the second direction D2, the first groups and the second groups may be arranged at an interval ratio of 2n:2.

In an example embodiment, each of the second active lines ACT_N of the first groups may have the first width, and each of the second active lines ACT_N of the second groups may have the second width, but may have a width different from that of the first active lines ACT_P as illustrated in FIG. 4B according to example embodiments.

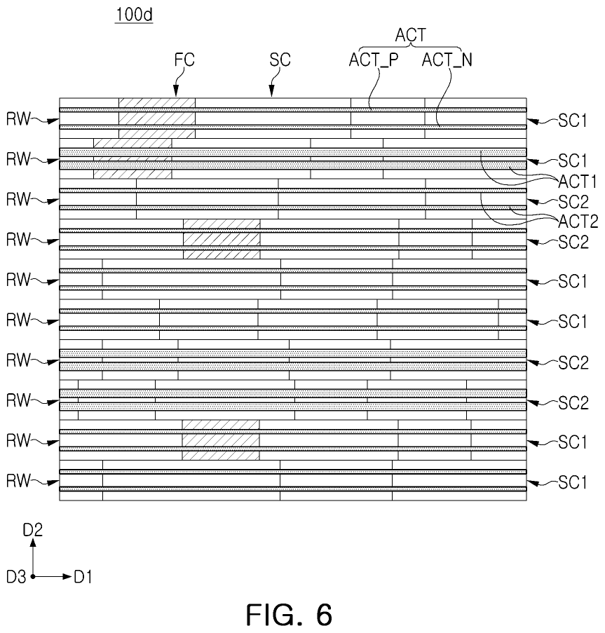

FIG. 6 is a schematic layout diagram of a semiconductor device according to example embodiments. FIG. 6 may be a layout, but may be understood as a plan view of an actual semiconductor device manufactured based on the layout.

Referring to FIG. 6, a semiconductor device 100d according to example embodiments may have a different arrangement from that of FIG. 5. In a plurality of adjacent rows RW, the first standard cells SC1 and the second standard cells SC2 may not be disposed at the interval ratio of 2n:2. That is, the first standard cells SC1 and the second standard cells SC2 may be arranged in a plurality of rows RW without a specific interval ratio.

In an example embodiment, the arrangement relationship of the standard cells SC of the semiconductor device 100c may be formed based on a layout diagram corrected through the feedback operation of FIG. 2. For example, unlike that described in FIG. 5, in the floorplan operation S110 or the placement operation S130, standard cells having base active regions ACT having different widths may be arranged in each of the site rows to form a tapered pattern, and thereafter, standard cells having the base active regions ACT having the same width may be disposed in each of the site rows, and the tapered pattern may then be removed. The feedback operation may be performed in consideration of an area of the substrate or the electrical performance of the device. Accordingly, a semiconductor device having a desired or optimized degree of integration and electrical performance may be provided.

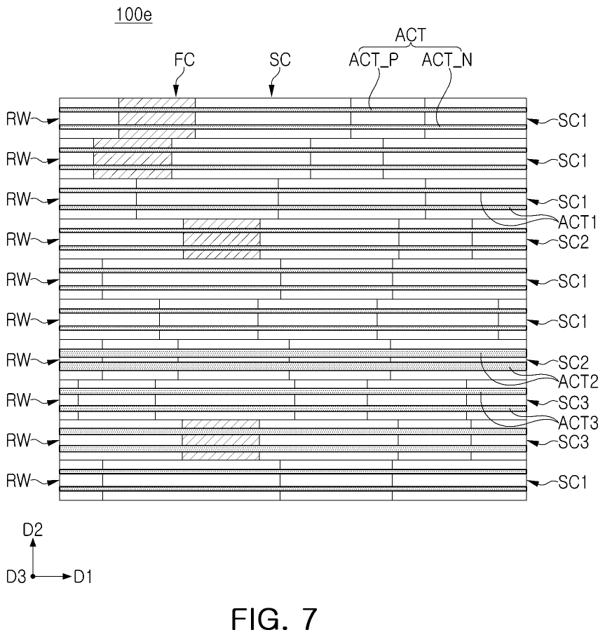

FIG. 7 is a schematic layout diagram of a semiconductor device according to example embodiments. FIG. 7 may be a layout, but may be understood as a plan view of an actual semiconductor device manufactured based on the layout.

Referring to FIG. 7, a semiconductor device 100e according to example embodiments may further include third standard cells SC3 unlike FIGS. 3A to 6.

The third standard cells SC3 may be arranged in a third row on the substrate 101. The third standard cells SC3 may have different widths (defined in the second direction D2), while having the same cell height in the third row. The cell height of the third standard cells SC3 may be the same as the cell height of the first and second standard cells SC1 and SC2.

Each of the third standard cells SC3 may include a third base active region ACT3. In this specification, the first active line ACT_P of the third standard cells SC3 may be referred to as a ‘fifth active line’, and the second active line ACT_N may be referred to as a ‘sixth active line’.

The third base active regions ACT3 of the third standard cells SC3 may have the same third width and be arranged in the first direction D1 in the third row. In this specification, the width of the base active regions ACT3 may refer to the width of the first active line ACT_P.

The third width of the third base active region ACT3 may be different from the first width W1 of the first base active region ACT1 (refer to FIG. 3B) and the second width W2 of the second base active region ACT2 (refer to FIG. 3B). The semiconductor device 100e according to example embodiments may further includes a base active region having a width different from that of the first and second base active regions ACT1 and ACT2 or standard cells including the same, so that electrical performance and/or the degree of integration may be improved. That is, a semiconductor device having improved electrical performance and integration may be provided by securing diversity of standard cells provided in the same library according to device characteristics. In the present example embodiment, only the third base active regions or third standard cells are described as an example, but otherwise, base active regions having various widths and standard cells including the same may also be provided.

The base active regions ACT1, ACT2, and ACT3 may further include third groups including third base active regions ACT3. In each of the third groups, the third base active regions ACT3 may include first active lines ACT_P having the third width and arranged in the first direction D1 in one of the plurality of rows RW. In each of the third groups, the first active lines ACT_P may have the same width. The third groups may be arranged at regular intervals from the first and second groups in the second direction D2.

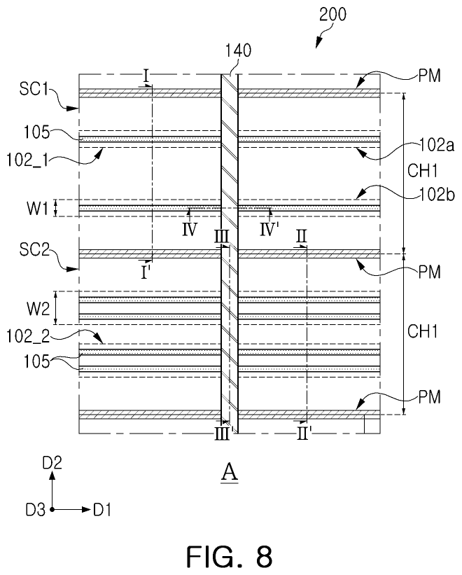

FIG. 8 is a plan view illustrating a semiconductor device according to example embodiments. FIG. 8 is a plan view illustrating a region corresponding to region ‘A’ of FIG. 3.

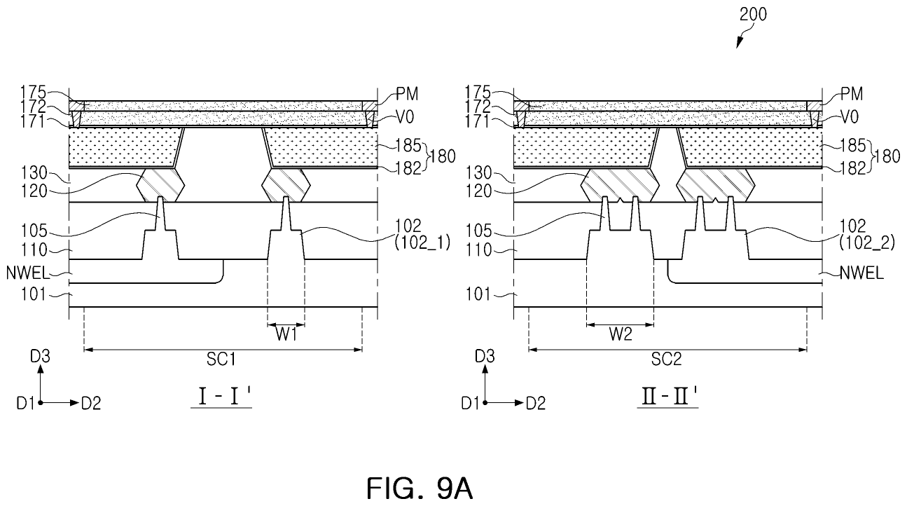

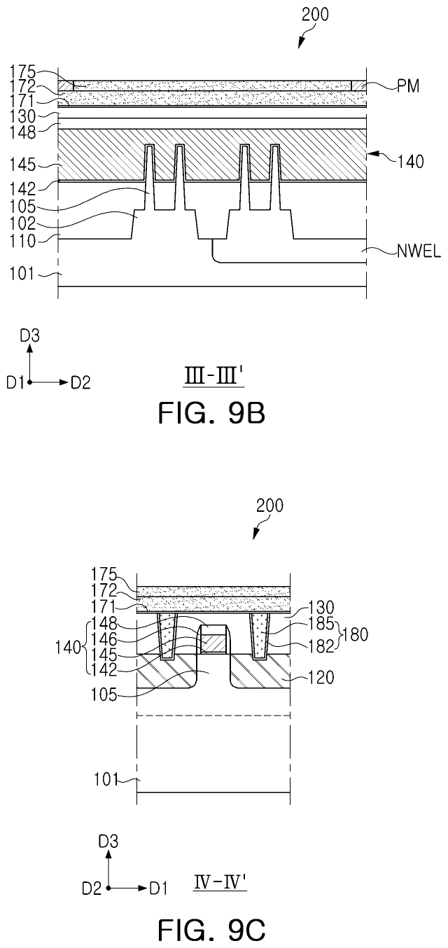

FIGS. 9A to 9C are cross-sectional views illustrating semiconductor devices according to example embodiments. FIG. 9A is a cross-sectional view taken along lines I-I′ and II-IF of FIG. 8, FIG. 9B is a cross-sectional view taken along line of FIG. 8, and FIG. 9C is a cross-sectional view taken along line IV-IV′ of FIG. 8.

Referring to FIGS. 8 to 9C, a semiconductor device 200 may include a substrate 101, active regions 102 having at least one active fin 105, a device isolation layer 110, source/drain regions 120, a gate structure 140 having a gate electrode 145, an interlayer insulating layer 130, a contact structure 180, first and second dielectric layers 172 and 175, and power lines PM. The semiconductor device 200 according to example embodiments may further include an etch stop layer 171 disposed on the interlayer insulating layer 130.

The semiconductor device 200 may include FinFet devices in which the active regions 102 are transistors respectively including active fins 105 having a fin structure.

The substrate 101 may have an upper surface extending in the first direction D1 and the second direction D2. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, a semiconductor on insulator (SeOI) layer, or the like. The substrate 101 may include doped regions such as an N well region NWELL.

The device isolation layer 110 may define active regions 102 in the substrate 101. The device isolation layer 110 may be formed by, for example, a shallow trench isolation (STI) process. As illustrated in FIG. 9A, the device isolation layer 110 may include a region extending deeper to a lower portion of the substrate 101 between adjacent active regions 102, but embodiments are not limited thereto. The device isolation layer 110 may have an upper portion on a lower level than an upper portion of the active regions 102. Accordingly, the device isolation layer 110 may partially expose upper portions of the active regions 102. In some example embodiments, the device isolation layer 110 may have a curved upper surface having a higher level toward the active fins 105. The device isolation layer 110 may be formed of an insulating material, and may include, for example, oxides, nitrides, or combinations thereof.

In an example embodiment, the first standard cells SC1 arranged in a first row and the second standard cells SC2 arranged in a second row adjacent to the first row may be disposed on the substrate 101, similar to those described above with reference to FIGS. 3A and 3B.

The active regions 102 are defined by the device isolation layer 110 in the substrate 101 and may be disposed to extend in the first direction D1. The active regions 102 may have the same characteristics as those described in the base active region ACT or the first active line ACT_P described with reference to FIGS. 3A and 3B. The active fins 105 may protrude from the active regions 102 in the third direction D3. The active fins 105 may extend in the first direction D1. Upper ends of the active fins 105 may protrude by a predetermined height from the upper surface of the device isolation layer 110. The active fins 105 may be formed as a portion of the substrate 101, or may include an epitaxial layer grown from the substrate 101. At both sides of the gate structure 140, the active fins 105 are partially recessed, and the source/drain regions 120 may be disposed on the recessed active fins 105.

In some example embodiments, the active regions 102 may have doped regions including impurities. For example, the active fins 105 may include impurities diffused from the source/drain regions 120 in a region in contact with the source/drain regions 120.

Each of the active regions 102 may include a first active region 102a and a second active region 102b extending parallel to each other. In an example embodiment, each of the standard cells SC1 and SC2 may include first and second active regions 102a and 102b. The first active region 102a and the second active region 102b may be active regions of different conductivity-types. For example, the first active region 102a may be an n-well region.

In an example embodiment, the active regions 102 include first active regions 102_1 and second active regions 102_2 defined by the device isolation layer 110 and extending in the first direction D1. The first active regions 102_1 may be active regions of the first standard cells SC1, and the second active regions 102_2 may be active regions of the second standard cells SC2. That is, the first active regions 102_1 have the same or similar characteristics as those of the first base active region ACT1 described above with reference to FIG. 3A, and the second active regions 102_2 may have the same or similar characteristics as those of the second base active region ACT2 described above with reference to FIG. 3A.

Each of the first and second active regions 102_1 and 102_2 may have a uniform width and extend in the first direction D1. Each of the first active regions 102_1 may have a first width W1, and each of the second active regions 102_2 may have a second width W2 greater than the first width W1.

In an example embodiment, the active fins 105 may include at least one first active fin 105_1 extending in the first direction D1 on the first active regions 102_1 and at least one second active fin 105_2 extending in the first direction D1 on the second active regions 102_2. The number of first active fins 105_1 may be smaller than the number of second active fins 105 2.

The source/drain regions 120 may be disposed on both sides of the gate structure 140 on regions in which the active fins 105 are recessed. In the present example embodiment, the source/drain region 120 may be an upper surface on a level higher than upper surfaces of the active fins 105 where the substrate 101 serves as a base reference layer by forming a recess in a partial region of the active fins 105 and performing selective epitaxial growth (SEG) on the recess. The source/drain regions 120 may serve as a source region or a drain region of the transistors. The upper surfaces of the source/drain regions 120 may be located on a level that is the same as or similar to a lower surface of the gate structure 140 in the cross-section shown in FIG. 9C. However, according to example embodiments, relative heights of the source/drain regions 120 and the gate structure 140 may be variously changed.

The source/drain regions 120 may have a merged shape connected to each other between the active fins 105 adjacent to each other in the second direction D2 as shown in FIG. 9A, but embodiments are not limited thereto. The source/drain regions 120 may have angled sides in the cross-section according to FIG. 9A. However, according to example embodiments, the source/drain regions 120 may have various shapes, for example, any one of a polygonal shape, a circular shape, an oval shape, and a rectangular shape.

The source/drain regions 120 may be formed of an epitaxial layer, and may include, for example, silicon (Si), silicon germanium (SiGe), or silicon carbide (SiC). In addition, the source/drain regions 120 may further include impurities such as arsenic (As) and/or phosphorus (P). In some example embodiments, the source/drain regions 120 may include a plurality of regions including elements having different concentrations and/or a doped element.

The gate structure 140 may cross the active fins 105 on the active regions 102 and extend in the second direction D2. Channel regions of transistors may be formed in the active fins 105 crossing the gate structure 140. The gate structure 140 may include a gate insulating layer 142, a gate electrode 145, gate spacer layers 146, and a gate capping layer 148.

The gate insulating layer 142 may be disposed between the active fins 105 and the gate electrode layer 165. In some example embodiments, the gate insulating layer 142 may be formed of a plurality of layers and/or may be disposed to extend to a side surface of the gate electrode 145. The gate insulating layer 142 may include an oxide, a nitride, and/or a high-k material. The high-k material may refer to a dielectric material having a dielectric constant higher than that of a silicon oxide layer (SiO₂).

The gate electrode 145 may include a conductive material, for example, a metal nitride such as titanium nitride (TiN), tantalum nitride (TaN), and/or tungsten nitride (WN), a metal material such as aluminum (Al), tungsten (W), and/or molybdenum (Mo), and/or a semiconductor material, such as doped polysilicon. The gate electrode 145 may include two or more multi-layers. The gate electrodes 145 may be separated from each other in the second direction D2 between at least some of the adjacent transistors according to a circuit configuration of the semiconductor device 200. For example, the gate electrodes 145 may be separated by a separate gate separation layer.

The gate spacer layers 146 may be disposed on both side surfaces of the gate electrode 145. The gate spacer layers 146 may insulate the source/drain regions 120 from the gate electrode 145. In some example embodiments, the gate spacer layers 146 may have a multi-layer structure. The gate spacer layers 146 may include oxide, nitride, and/or oxynitride, and in some embodiments, may include a low dielectric material. For example, the gate spacer layers 146 may include one or more materials including, but not limited to, SiO, SiN, SiCN, SiOC, SiON, and/or SiOCN.

The gate capping layer 148 may be disposed on the gate electrode 145, and a lower surface and side surfaces thereof may be at least partially surrounded by the gate electrode 145 and the gate spacer layers 146, respectively. For example, the gate capping layer 148 may include an oxide, a nitride, and/or an oxynitride.

The interlayer insulating layer 130 may be disposed to at least partially cover the source/drain regions 120 and the gate structure 140. The interlayer insulating layer 130 may include, for example, one or more materials including, but not limited to, an oxide, a nitride, and/or an oxynitride, and, in some embodiments, may include a low dielectric material.

The contact structure 180 may pass through the interlayer insulating layer 130 to connect to the source/drain regions 120 or pass through the interlayer insulating layer 130 and the gate capping layer 148 to connect to the gate electrode 145, and may be configured to apply an electrical signal to the source/drain regions 120 and the gate electrode 145. The contact structure 180 may be disposed to recess the source/drain regions 120 by a predetermined depth, but embodiments are not limited thereto. The contact structure 180 may include a conductive barrier 182 and a contact plug 185. For example, the contact plug 185 may include a metal material, such as tungsten (W), aluminum (Al), and/or copper (Cu) and/or a semiconductor material, such as doped polysilicon. Also, in some example embodiments, the contact structure 180 may further include a metal-semiconductor layer, such as a silicide layer, disposed at an interface in contact with the source/drain regions 120 and the gate electrode 145.

The first and second dielectric layers 172 and 175 may at least partially cover the contact structure 180 and may be disposed on the same level as a wiring structure, where the substrate 101 serves as a base reference layer, including a conductive via V0 and power lines PM. For example, the first and second dielectric layers 172 and 175 may include one or more materials including, but not limited to, SiO, SiN, SiCN, SiOC, SiON, and/or SiOCN. Each of the wiring structures may include one or more materials including, but not limited to, aluminum (Al), copper (Cu), and/or tungsten (W). In some example embodiments, the wiring structure may form an additional dielectric layer and additional wiring lines may be disposed at an upper level.

The power lines PM may be electrically connected to the contact structure 180 through the conductive via V0. Adjacent power lines PM may be configured to supply power having different potentials to each of the source/drain regions 120 as described with reference to FIGS. 3A and 3B, and one power line PM may be a shared power line for adjacent source/drain regions 120.

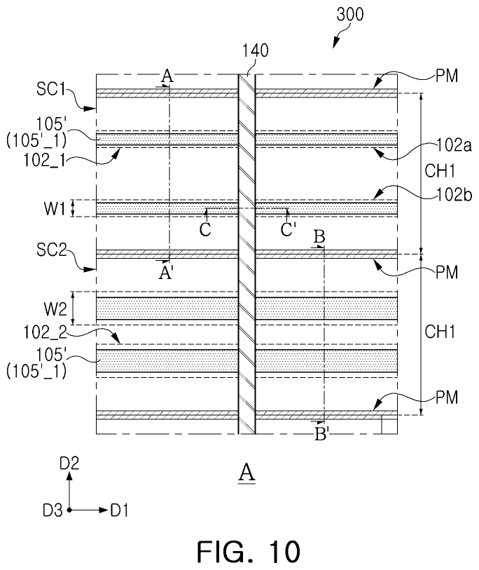

FIG. 10 is a plan view illustrating a semiconductor device according to example embodiments.

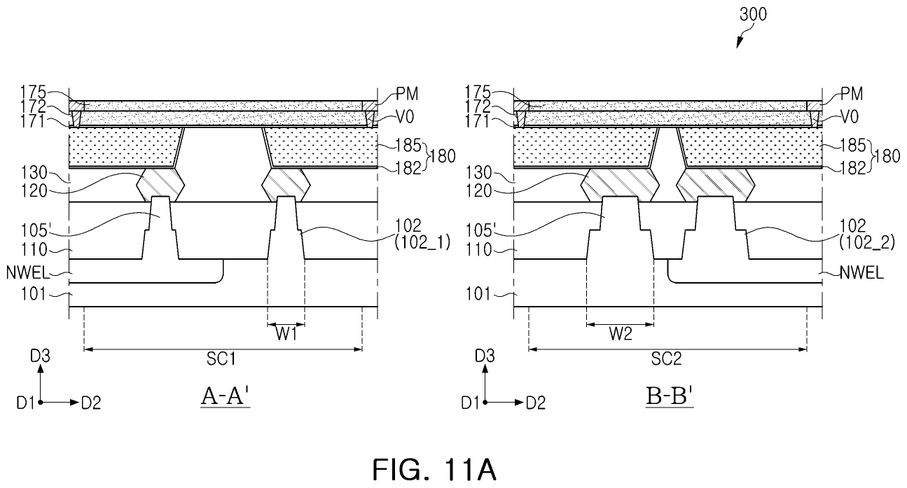

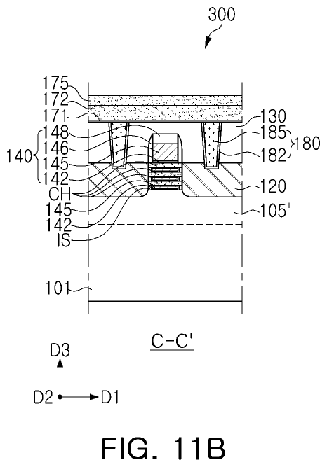

FIGS. 11A and 11B are cross-sectional views illustrating semiconductor devices according to example embodiments. FIG. 11A is a cross-sectional view taken along lines A-A′ and B-B′ of FIG. 10, and FIG. 11B is a cross-sectional view taken along line C-C′ of FIG. 10.

Referring to FIGS. 10 to 11B, unlike FIGS. 8 to 9C, a semiconductor device 300 may include a transistor having a multi-bridge channel FET (MBCFET™) structure, which is a transistor including a nanosheet.

The semiconductor device 300 may be understood as being similar to the semiconductor device 200 shown in FIGS. 8 to 9C, except that the active pattern in each base active region has a single structure and the active structure for the transistor is configured to include a plurality of nanosheets. In addition, the components of the present example embodiment may be understood with reference to the same or similar components of the semiconductor device 200 described above with reference to FIGS. 8 to 9, unless otherwise specified.

Referring to FIG. 10, in the semiconductor device 300 according to example embodiments, one fin-type active pattern 105′ may be disposed in the active region 102 of each transistor. Similar to the active fins 105 illustrated in FIGS. 8 to 9C, the fin-type active pattern 105′ protrudes from the upper surface of the active region 102 in the third direction D3 and extends in the first direction D1.

In an example embodiment, the fin-type active pattern 105′ may include first fin-type active patterns 105′_1 extending in the first direction D1 on the first active regions 102_1 and second fin-type active patterns 105′_2 extending in the first direction D1 on the second active regions 102_2.

Referring to FIGS. 11A and 11B, the semiconductor device 300 may further include a plurality of nanosheet-shaped channel layers CH spaced apart from each other vertically on the fin-type active pattern 105′ and internal spacer layers IS in parallel with the gate electrode 145 between the plurality of channels CH. However, in some example embodiments, the internal spacer layers IS may be omitted.

The semiconductor device 300 may include a gate-all-around type transistors in which the gate electrode 145 is disposed between the fin-type active pattern 105′ and the channel layers CH and between the plurality of channel layers CH. For example, the semiconductor device 300 may include transistors based on the channel layers CH, source/drain regions 120, and the gate electrode 145.

The plurality of channel layers CH may be disposed as two or a plurality of channel layers CH spaced apart from each other in the third direction D3 on the fin-type active patterns 105′. The plurality of channel layers CH may be spaced apart from upper surfaces of the fin-type active patterns 105′, while being connected to the source/drain regions 120. The plurality of channel layers CH may have a width that is the same as or similar to that of the fin-type active patterns 105′ in the second direction D2, and may have a width that is the same as or similar to that of the gate structure 140 in the first direction D1.

The plurality of channel layers CH may be formed of a semiconductor material, and may include, for example, one or more materials including, but not limited to, silicon (Si), silicon germanium (SiGe), and/or germanium (Ge). The plurality of channel layers CH may be formed of, for example, the same material as the substrate 101 (particularly, the active region). The number and shape of the channel layers CH constituting one channel structure may be variously changed in example embodiments. For example, in some example embodiments, a channel layer may be further positioned in a region in which the fin-type active pattern 105′ contacts the gate electrode 145.

In an example embodiment, the plurality of channel layers CH may include first channel layers vertically spaced apart from each other on the first fin-type active patterns 105′_1 and second channel layers vertically spaced apart from each other on the second fin-type active patterns 105′_2. A width of the first channel layers may be smaller than a width of the second channel layers.

The gate structure 140 may cross the fin-type active pattern 105′ and the plurality of channel layers CH on top of the fin-type active pattern 105′. Channel regions of transistors may be formed in the fin-type active pattern 105′ crossing the gate structure 140 and the plurality of channel layers CH. In the present example embodiment, the gate insulating layer 142 may be disposed not only between the fin-type active pattern 105′ and the gate electrode 145 but also between the plurality of channel layers CH and the gate electrode 145. The gate electrode 145 may be disposed on the fin-type active pattern 105′ to at least partially fill portions between the plurality of channel layers CH and to extend over the plurality of channel layers CH. The gate electrode 145 may be spaced apart from the plurality of channel layers CH by the gate insulating layer 142.

The internal spacers IS may be disposed in parallel with the gate electrode 145 between the plurality of channel layers CH. The gate electrode 145 may be spaced apart from the source/drain regions 120 by the internal spacers IS to be electrically separated. Side surfaces of the internal spacers IS facing the gate electrode 145 may be flat or may be rounded to be convex inwardly toward the gate electrode 145. The internal spacers IS may be formed of oxide, nitride, and/or oxynitride, and, in some embodiments, a low-k film.

As described above, the semiconductor device according to the present example embodiment may be applied to transistors having various structures. In addition to the example embodiments described above, the semiconductor device according to the present example embodiment may also be implemented as a semiconductor device including a vertical FET (VFET) having an active region extending perpendicular to the upper surface of the substrate 101 and a gate structure at least partially surrounding the active region or a semiconductor device including a negative capacitance FET (NCFET) using a gate insulating layer having ferroelectric properties.

When the standard cells having the same cell height are arranged, the base active region having the same width is disposed in one row, thereby providing a semiconductor device having reduced process defects due to a tapered pattern and improved productivity. In addition, a semiconductor device having improved electrical performance may be provided by arranging base active regions having different widths in each row.

While example embodiments have been shown and described above, it will be apparent to those skilled in the art that modifications and variations could be made without departing from the scope of the present inventive concept as defined by the appended claims.

What is claimed is:

1. A semiconductor device comprising:
first standard cells arranged in a first row on a substrate and respectively including a first base active region;
second standard cells arranged in a second row adjacent to the first row on the substrate and respectively including a second base active region;
a power line extending in a first direction along a boundary between the first standard cells and the second standard cells; and
a device isolation layer on side surfaces of the first and second base active regions,
wherein, in a plan view, the first standard cells and the second standard cells have a same cell height,
the first base active region of each of the first standard cells includes a first active line having a first conductivity-type and a second active line having a second conductivity-type, different from the first conductivity-type,
the second base active region of each of the second standard cells includes a third active line having the first conductivity-type and a fourth active line having the second conductivity-type,
the first active lines of the first standard cells arranged in the first row have a same first width,
the third active lines of the second standard cells arranged in the second row have a same second width, and
the first width is narrower than the second width.

2. The semiconductor device of claim 1, wherein
the second active line has a width substantially equal to the first width, and
the fourth active line has a width substantially equal to the second width.

3. The semiconductor device of claim 1, wherein
the second active line has a third width, different from the first width, and
the fourth active line has a fourth width, different from the second width.

4. The semiconductor device of claim 3, wherein
a distance between the first active line and the power line is less than a distance between the second active line and the power line, and
a distance between the third active line and the power line is less than a distance between the fourth active line and the power line.

5. The semiconductor device of claim 3, wherein
each of the first standard cells has a first side and a second side opposing each other in a second direction, perpendicular to the first direction, and a first central axis between the first side and the second side,
each of the second standard cells has a third side and a fourth side opposing each other in the second direction and a second central axis between the third side and the fourth side,
each of the first active lines has a fifth side and a sixth side opposing each other in the second direction and a third central axis between the fifth side and the sixth side,
each of the third active lines has a seventh side and an eighth side opposing each other in the second direction and a fourth central axis between the seventh side and the eighth side, and
a first distance from the first central axis to the third central axis is greater than a second distance from the second central axis to the fourth central axis.

6. The semiconductor device of claim 3, wherein
each of the first standard cells has a first side and a second side opposing each other in a second direction, perpendicular to the first direction, and a first central axis between the first side and the second side,
each of the second standard cells has a third side and a fourth side opposing each other in the second direction and a second central axis between the third side and the fourth side,
each of the first active lines has a fifth side and a sixth side opposing each other in the second direction and a third central axis between the fifth side and the sixth side,
each of the third active lines has a seventh side and an eighth side opposing each other in the second direction and a fourth central axis between the seventh side and the eighth side, and
a first distance from the first central axis to the third central axis is substantially equal to a second distance from the second central axis to the fourth central axis.

7. The semiconductor device of claim 1, wherein
each of the first standard cells further includes at least one first active fin extending in the first direction on the first active line,
each of the second standard cells further includes at least one second active fin extending in the first direction on the third active line, and
a number of first active fins is less than a number of second active fins.

8. The semiconductor device of claim 1, wherein
each of the first standard cells further includes first channel layers vertically spaced apart from each other on the first active line,
each of the second standard cells further includes second channel layers vertically spaced apart from each other on the second active line, and
a width of the first channel layers is smaller than a width of the second channel layers.

9. The semiconductor device of claim 1, further comprising:
third standard cells arranged in a third row on the substrate and respectively including a third base active region, and
wherein in the plan view, the third standard cell has a same cell height as each of the first and second standard cells.

10. The semiconductor device of claim 9, wherein
the third base active region includes a fifth active line having the first conductivity-type and a sixth active line having the second conductivity-type,
the fifth active lines of the third standard cells arranged in the third row have the same third width, and
the third width is different from the first width and the second width.

11. A semiconductor device comprising:
a substrate having base active regions extending in a first direction;
a plurality of standard cells respectively including a gate structure extending in a second direction, crossing the first direction, on the base active regions, and source/drain regions on the base active regions at both sides of the gate structure; and
a plurality of power lines respectively extending in the first direction along boundaries of the plurality of standard cells and configured to supply power to the plurality of standard cells,
wherein the plurality of standard cells are arranged in a plurality of rows having a same cell height in the second direction,
each of the base active regions includes a first active line having a first conductivity-type and a second active line having a second conductivity-type, different from the first conductivity-type,
the base active regions include first groups including first base active regions and second groups including second base active regions,
in each of the first groups, the first base active regions include the first active lines having a first width and arranged in the first direction in one of the plurality of rows, and
in each of the second groups, the second base active regions include the first active lines having a second width, different from the first width, and arranged in the first direction in one of the plurality of rows,
wherein the first groups and the second groups are arranged at regular intervals in the second direction.

12. The semiconductor device of claim 11, wherein
the first width is narrower than the second width, and
in the second direction, the first groups and the second groups are arranged at an interval ratio of 2n:2, respectively.

13. The semiconductor device of claim 12, wherein n is an integer in a range of 1 to 4.

14. The semiconductor device of claim 11, wherein,
in each of the first groups, the first active lines have a same width as each other, and
in each of the second groups, the first active lines have a same width as each other.

15. The semiconductor device of claim 11, wherein
the base active regions further include third groups including third base active regions, and
in each of the third groups, the third base active regions include the first active lines having a third width and arranged in the first direction and in one of the plurality of rows,
the third width is different from the first width and the second width, and
wherein the third groups are arranged at regular intervals from the first groups and the second groups in the second direction.

16. The semiconductor device of claim 11, wherein
each of the second active lines of the first groups has the first width, and
each of the second active lines of the second groups has the second width.

17. A semiconductor device comprising:
a substrate having a base active region;
a plurality of standard cells arranged in a plurality of rows on the substrate; and
a plurality of power lines extending in a first direction along boundaries of the plurality of standard cells and configured to supply power to the plurality of standard cells,
wherein each of the plurality of standard cells includes a gate structure extending in a second direction, crossing the first direction, on the base active region, and source/drain regions on the base active region at both sides of the gate structure,
the plurality of power lines extend parallel to each other at equal intervals, and
the base active region includes first and second base active regions having different widths in different rows among the plurality of rows and arranged in the first direction.

18. The semiconductor device of claim 17, wherein
in a plan view, the plurality of standard cells in the plurality of rows have a same cell height,
each of the first base active regions has a same first width as each other, and
each of the second base active regions has a same second width as each other.

19. The semiconductor device of claim 17, wherein
the plurality of standard cells include first standard cells on the first base active regions and second standard cells on the second base active regions, and
in a plurality of adjacent rows, the first standard cells and the second standard cells are arranged at an interval ratio of 2n:2.

20. The semiconductor device of claim 19, wherein
the plurality of power lines include a first power line extending in the first direction between the first standard cells arranged in a first row among the plurality of rows and the second standard cells arranged in a second row among the plurality of rows, and
a distance from the first power line to the first base active region in the first row is substantially equal to a distance from the first power line to the second base active region in the second row.
